(19) United States
(12) Patent Application Publication
(10) Pub. No.: US 2020/0041543 A1
(43) Pub. Date: Feb. 6, 2020

(54) PROBE STRUCTURE AND METHOD FOR PRODUCING PROBE STRUCTURE

(71) Applicant: Nidec-Read Corporation, Kyoto (JP)

(72) Inventors: Michihisa MAEDA, Kyoto (JP); Kiyoshi NUMATA, Kyoto (JP); Hidekazu YAMAZAKI, Kyoto (JP); Makoto FUJINO, Kyoto (JP)

(73) Assignee: Nidec-Read Corporation, Kyoto (JP)

(21) Appl. No.: 16/495,842

(22) PCT Filed: Mar. 14, 2018
(86) PCT No.: PCT/JP2018/009957

§ 371 Date: Sep. 20, 2019

(30) Foreign Application Priority Data
Mar. 21, 2017 (JP) 2017-054640

(51) Int. Cl. G01R 1/067; B82Y 40/00; C01B 32/166; C01B 32/162

(52) U.S. Cl. CPC G01R 1/06761; C01B 32/162; C01B 32/166; B82Y 40/00

(57) ABSTRACT

A probe structure is provided with: a holding plate which has a first surface and a second surface in which at least the first surface is insulated; a plurality of electrodes which are formed on the first surface of the holding plate in such a state that the plurality of electrodes is separated from each other; and carbon nanotube structures which are erected on the electrodes 3. The holding plate is provided with through holes which correspond to the electrodes, respectively.

### BACKGROUND OF THE INVENTION

### Technical Field

The present invention relates to a probe structure used in a jig for substrate inspection or the like and a producing method thereof.

### Related Art

Conventionally, a carbon nanotube (CNT) is expected to be used as an electronic device material, an optical material, a conductive material, a bio-related material or the like. It is known that multiple carbon nanotubes are collected to form a bulk aggregate. In addition, a method is known in which in order to make the bulk aggregate large scaled and improve properties such as purity, specific surface area, electrical conductivity, density, hardness and the like, a catalysts is arranged on a substrate to make plural carbon nanotubes grown by chemical vapor deposition (CVD) on a substrate surface. It is proposed that in this method, part of a bundle of the carbon nanotubes obtained by an aligned growth of the plural carbon nanotubes is soaked in a liquid and dried afterwards, thereby producing an aligned carbon nanotube bulk structure having high density parts with a density of 0.2-1.5 g/cm³ and low density parts with a density of 0.001-0.2 g/cm³ (for example, see patent literature 1).

### LITERATURE OF RELATED ART

### Patent literature

Patent literature 1: Japanese Laid-Open No. 2007-181899

### SUMMARY

Meanwhile, after the aligned carbon nanotube bulk structure disclosed in patent literature 1 is produced as the bulk aggregate of the plural carbon nanotubes which are grown in the presence of the catalyst arranged on the substrate, the aligned carbon nanotube bulk structure is used as an electronic device material, a conductive material or the like in a state that a base end portion of the aligned carbon nanotube bulk structure is physically, chemically or mechanically peeled from the substrate.

However, when the aligned carbon nanotube bulk structure is used as, for example, a probe structure for detecting electrical signals, such as a jig for substrate inspection or the like, it is necessary to connect the base end portion of the aligned carbon nanotube bulk structure peeled from the substrate to an electrode portion or the like for transmitting the signals to a control portion and the like of an inspection apparatus. Due to an occurrence of contact resistance in the connection portion, an electrical resistance of the probe structure is inevitably increased to about several ohms and becomes a high resistance.

The present invention provides a probe structure in which an electrical resistance of the probe structure is prevented from increasing and excellent electrical conductivity is obtained and a producing method thereof.

The probe structure according to one aspect of the present invention includes a holding plate that has a first surface and a second surface in which at least the first surface is insulated, a plurality of electrodes which is formed on the first surface of the holding plate in a state that the plurality of electrodes is separated from each other, and carbon nanotube structures which are erected on the electrodes. Through holes which correspond to the electrodes are formed on the holding plate.

The method for producing probe structure according to one aspect of the present invention includes an electrode forming process in which a plurality of electrodes is formed on a first surface of a holding plate in the state that the plurality of electrodes is separated from each other, wherein the holding plate has the first surface and a second surface, and at least the first surface is insulated, a catalyst arranging process in which catalysts are arranged on the plurality of electrodes, a carbon nanotube structure generating process in which a plurality of carbon nanotubes is grown by chemical vapor deposition in the presence of the catalysts to generate carbon nanotube structures on the electrodes respectively, and a through hole forming process in which through holes corresponding to the electrodes respectively are formed in the holding plate.

### BRIEF DESCRIPTION OF THE DRAWINGS

FIG. 1 is a cross-sectional view showing a first embodiment of a probe structure according to the present invention.

FIG. 2 is a process chart showing a method for producing the probe structure according to the first embodiment.

FIG. 3A is an illustration diagram showing a producing process of the probe structure according to the first embodiment.

FIG. 3B is an illustration diagram showing a producing process of the probe structure according to the first embodiment.

FIG. 3C is an illustration diagram showing a producing process of the probe structure according to the first embodiment.

FIG. 3D is an illustration diagram showing a producing process of the probe structure according to the first embodiment.

FIG. 3E is an illustration diagram showing a producing process of the probe structure according to the first embodiment.

FIG. 3F is an illustration diagram showing a producing process of the probe structure according to the first embodiment.

FIG. 4A is a perspective view showing a formation procedure of carbon nanotube structures which configure the probe structure.

FIG. 4B is a perspective view showing a formation procedure of carbon nanotube structures which configure the probe structure.

FIG. 5 is an illustration diagram showing an example in which the probe structure according to the first embodiment is used as an inspection jig of a substrate inspection apparatus.

FIG. 6 is a process chart showing a second embodiment of a method for producing probe structure according to the present invention.

FIG. 7 is a cross-sectional view showing another example of the probe structure shown in FIG. 1.

### DESCRIPTION OF THE EMBODIMENTS

Embodiments of the present invention are described below based on the drawings. Furthermore, configurations denoted by the same symbols in each diagram indicate the same configurations, and description thereof is omitted.

### First Embodiment

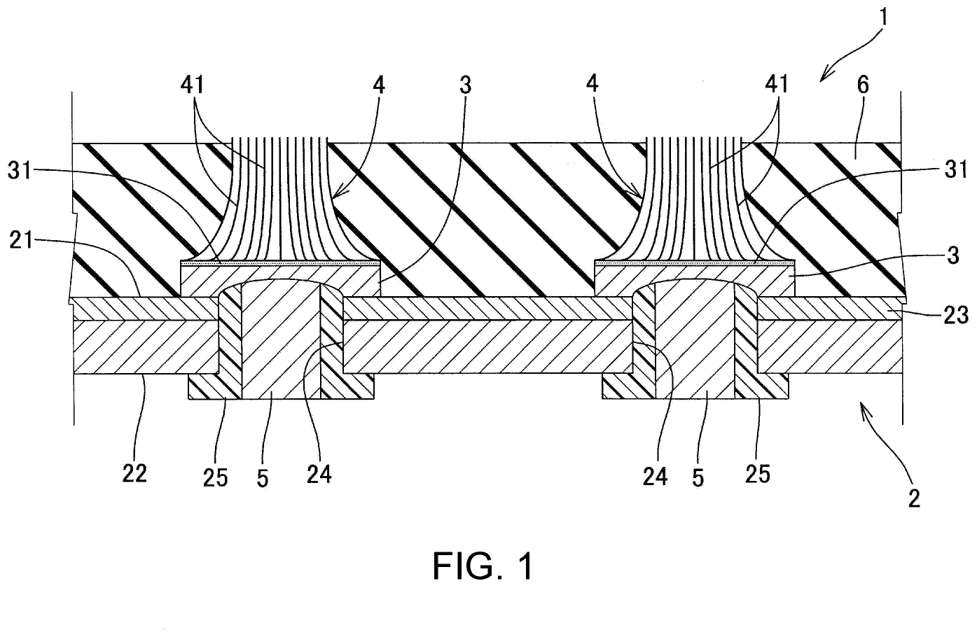

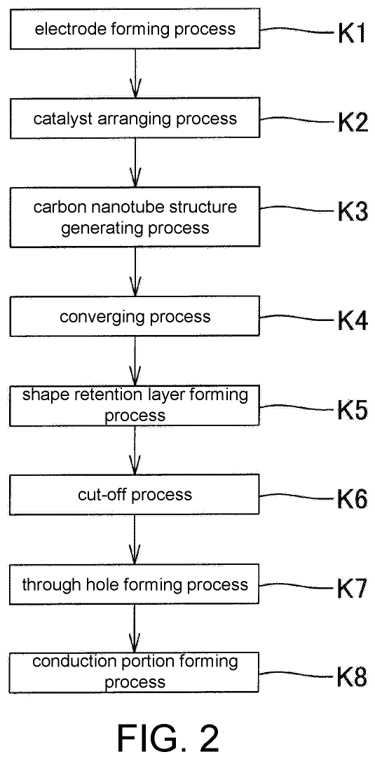

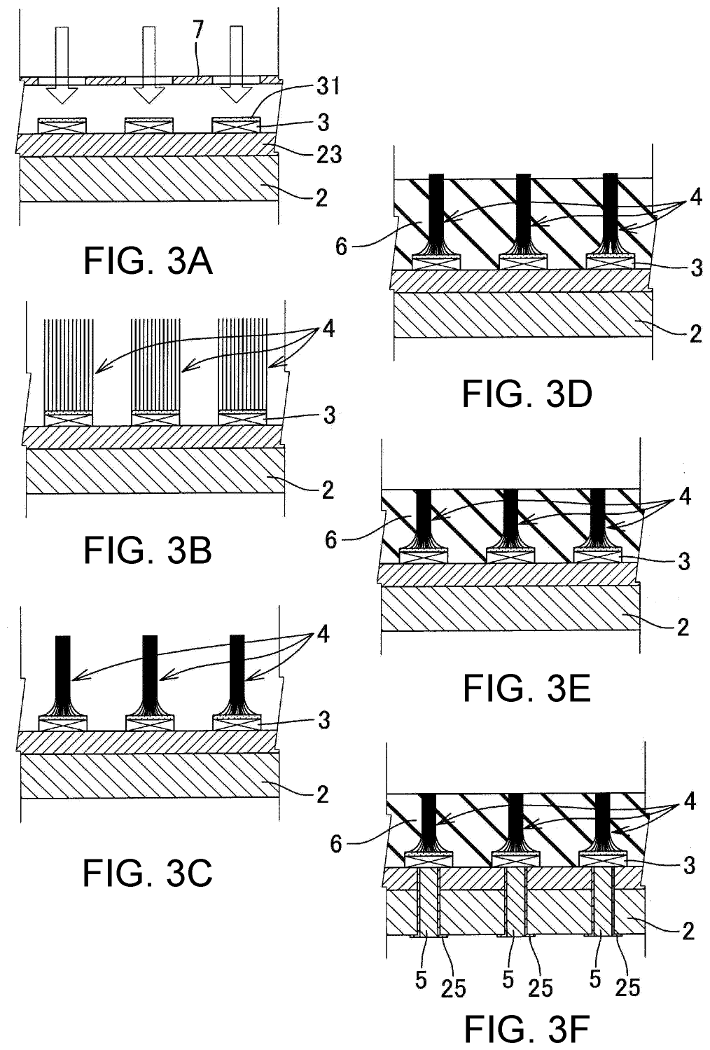

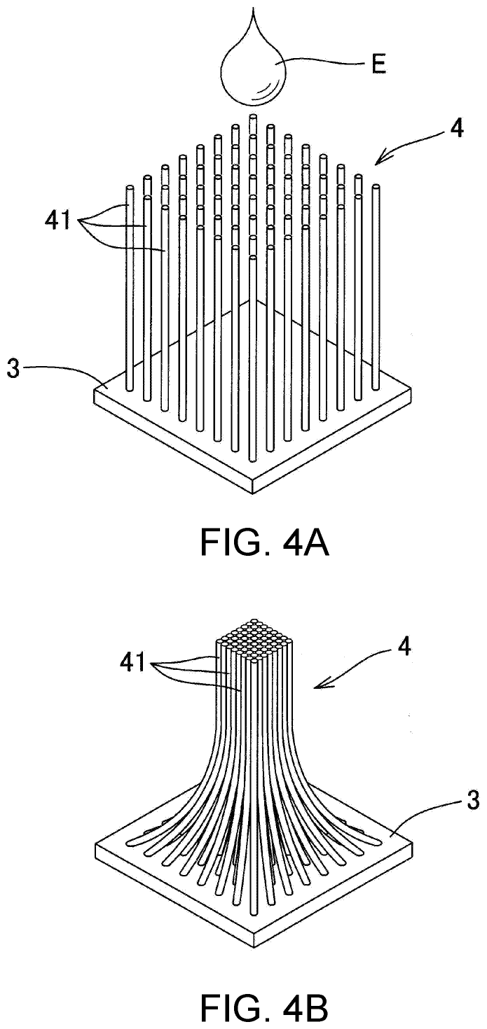

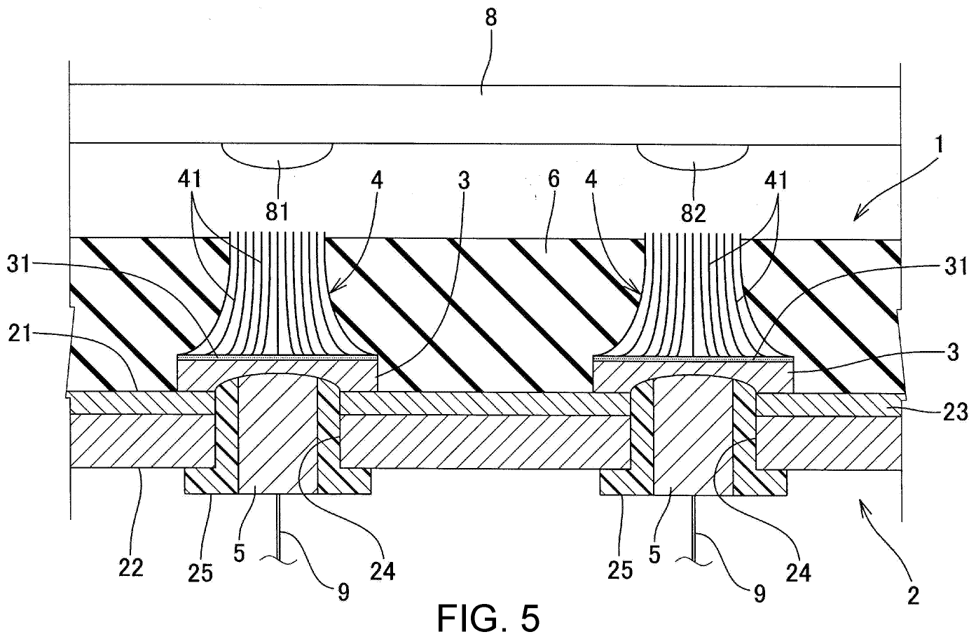

FIG. 1 is a cross-sectional view showing a first embodiment of a probe structure according to the present invention. FIG. 2 is a process chart showing a method for producing the probe structure 1. FIG. 3A-FIG. 3F are illustration diagrams showing producing processes of the probe structure 1. FIG. 4A and FIG. 4B are perspective views showing a formation procedure of carbon nanotube structures 4 which configure the probe structure 1. FIG. 5 is an illustration diagram showing an example in which the probe structure 1 is used as an inspection jig of a substrate inspection apparatus.

The probe structure 1 includes a holding plate 2 having a first surface 21 and a second surface 22, a plurality of electrodes 3 formed on the first surface 21 of the holding plate 2 in a state that the electrodes 3 are separated from each other, and carbon nanotube structures 4 respectively erected on each electrode 3.

The holding plate 2 comprises a crystal silicon substrate or the like in which at least the first surface 21 is insulated by being covered by an insulation film 23 made of silicon dioxide (SiO₂). Furthermore, the entire holding plate 2 may be formed into an insulation structure by forming the holding plate 2 with a ceramic material, a glass material or the like having insulation property. When the holding plate 2 is formed into an insulation structure, the probe structure 1 may not include the insulation film 23 and insulation layers 25.

In addition, through holes 24 which communicate the first surface 21 with the second surface 22 are formed on positions corresponding to each electrode 3, and conduction portions 5 extending from the electrodes 3 arranged on the first surface 21 through the through holes 24 to the second surface 22 are arranged on the holding plate 2. Inner surfaces of the through holes 24 are insulated by the insulation layers 25.

The electrodes 3 are formed into an island shape with a width of about 0.01 mm-0.2 mm and a thickness of about 0.1 μm-9 μm by masking the first surface 21 of the holding plate 2 and patterning a metal material of gold, silver, copper or aluminum in predetermined positions. In addition, catalysts 31 including iron, nickel or cobalt are arranged by vapor deposition or the like on each electrode 3. Thicknesses of the catalysts 31 may be 1 nm or more and 100 nm or less, and may be 1 nm or more and 5 nm or less.

Furthermore, the electrodes 3 may be configured by a catalyst material such as iron, nickel, cobalt and the like which also functions as the catalyst, or the electrodes 3 and the catalysts 31 may be configured integrally by mixing these catalyst materials into the electrodes 3.

The carbon nanotube structures 4 includes bulk aggregates of the carbon nanotubes 41 formed by using a conventionally well-known CVD apparatus (not shown) to make plural f single-layer or multi-layer carbon nanotubes 41 grow collectively by chemical vapor deposition in the presence of the catalysts 31. In the carbon nanotube structures 4 including the bulk aggregates of the carbon nanotubes 41, middle parts and parts on top end side are converged with a density higher than the density of rising parts rising from the electrodes 3 as described below. That is, with regard to a thickness (a diameter) of the carbon nanotube structures 4, the middle parts and the parts on the top end side is thinner than the rising parts rising from the electrodes 3.

The carbon nanotubes 41 configuring the carbon nanotube structures 4 have an outer diameter of 1 nm-20 nm and an erection length of 200 μm-2 mm. A range of the outer diameter of the carbon nanotubes 41 may be 10 nm-15 nm, and a range of the erection length may be 200 μm-500 μm.

A density (the number per unit cross section) of the carbon nanotube structures 4 in the rising part rising from the electrodes is 10¹⁰/cm²-10¹¹/cm², and a density of the middle part and the part on the top end side of the carbon nanotube structures 4 are about 5-20 times of the density in the rising part. Furthermore, this density ratio is not necessary as long as the middle part (approximately in the center in a length direction) have a higher density than the rising part of the carbon nanotube structures 4.

In addition, the carbon nanotube structures 4 are surrounded by a shape retention layer 6 made of silicone rubber or the like having insulation property and elasticity. In addition, top end portions of the carbon nanotube structures 4 are set in a state of being exposed from a surface of the shape retention layer 6.

As shown in FIG. 2, a method for producing the probe structure 1 includes an electrode forming process K1 in which a plurality of electrodes 3 is formed separated from each other on the first surface 21 of the holding plate 2, a catalyst arranging process K2 in which the catalysts 31 are respectively arranged on each electrode 3, a carbon nanotube structure generating process (a CNT structure generating process) K3 in which the plural carbon nanotubes 41 are grown by chemical vapor deposition in the presence of the catalysts 31 to generate the carbon nanotube structures 4 on each electrode 3, a converging process K4 in which at least the middle parts of the carbon nanotube structures 4 are converged with a high density, a shape retention layer forming process K5 in which the shape retention layer 6 having insulation property and elasticity is formed, a cut-off process K6 in which the top end portions of the carbon nanotube structures 4 and the surface of the shape retention layer 6 are cut off, a through hole forming process K7 in which the through holes 24 corresponding to each electrode 3 are formed on the holding plate 2, and a conduction portion forming process K8 in which a material having electrical conductivity is filled into each through hole 24 to form the conduction portions 5.

In the electrode forming process K1, as shown in FIG. 3A, in a state that a metal mask 7 in which openings are formed on forming positions of the electrodes 3 is arranged above the holding plate 2, the plurality of electrodes 3 is formed on the first surface 21 of the holding plate 2 by the patterning of a metal material of gold, silver, copper, aluminum or the like. Thereafter, in the catalyst arranging process K2, the catalysts 31 made of an iron chloride film, an iron film, an iron-molybdenum film, an alumina-iron film, an alumina-cobalt film, an alumina-iron-molybdenum film or the like is respectively arranged on each electrode 3 by sputter deposition or the like.

Then, in the CNT structure generating process K3, a CVD apparatus not shown is used to inject carbon-containing hydrocarbons, especially lower hydrocarbons such as methane, ethane, propane, ethylene, propylene, acetylene or the like and heat the carbon-containing hydrocarbons to a temperature of 500° C. or higher. In this way, as shown in FIG. 3B and FIG. 4A, plural single-layer or multi-layer carbon nanotubes 41 are grown collectively by chemical vapor deposition, and the carbon nanotube structures 4 including the bulk aggregates of the carbon nanotubes 41 are generated on the electrodes 3.

When the carbon nanotubes 41 are grown by chemical vapor deposition, it may use an atmosphere gas that does not react with the carbon nanotubes 41, such as helium, argon, hydrogen, nitrogen, neon, krypton, carbon dioxide, chlorine or the like. In addition, an atmosphere pressure of the reaction may be 10² Pa or more and 10⁷ Pa or less, may be 10⁴ Pa or more and 3×10⁵ Pa or less, and may be 5×10⁴ Pa or more and 9×10⁴ Pa or less.

Next, in the converging process K4, droplets E including, for example, water, alcohols (isopropanol, ethanol, methanol), acetones (acetone), hexane, toluene, cyclohexane, DMF (dimethylformamide) and the like are dripped from above the carbon nanotube structures 4 into the space between the plural carbon nanotubes 41, and thereby the carbon nanotube structures 4 are soaked in the liquid. Then, the carbon nanotube structures 4 are dried by natural drying at room temperature, vacuum drying or heating with a hot plate or the like.

As a result, a zipper effect is exhibited by a surface tension generated by dripping the droplets E and a Van der Waals force generated between the carbon nanotubes 41, and each carbon nanotube 41 is drawn to each other to converge the carbon nanotube structures 4. At this time, base end portions of the carbon nanotube structures 4 are fixed to the electrodes 3, and thus as shown in FIG. 3C and FIG. 4B, the middle parts of the carbon nanotube structures 4 and the parts on the upper sides of the middle parts are converged further than the rising parts of the carbon nanotube structures 4 rising from the electrodes 3 to have a higher density.

Furthermore, the top end portions of the carbon nanotube structures 4 are free ends and thus spread easily. Therefore, it is sufficient that the carbon nanotube structures 4 are converged on the whole, and at least the middle parts of the carbon nanotube structures 4 is thinner than the rising parts of the carbon nanotube structures 4. The top end portions of the carbon nanotube structures 4 may be partly spread to be thicker than the rising parts of the carbon nanotube structures 4.

In addition, if the strength and the electrical conductivity of the carbon nanotube structures 4 are sufficiently obtained, the converging process K4 may be omitted.

Thereafter, in the shape retention layer forming process K5, as shown in FIG. 3D, after a filling material having fluidity, such as a silicone-based elastomer is filled to surround the carbon nanotube structures 4, the filling material is cured to form the shape retention layer 6 having insulation property and elasticity.

Various materials including a rubber material, a flexible plastic material, a curable liquid rubber and the like can be used as the filling material having fluidity. Various liquid rubbers such as an RTV (Room Temperature Vulcanizing) silicone rubber, a heat curing silicone rubber, an ultraviolet curing silicone rubber and the like can be used as the liquid rubber. For example, an RTV silicone rubber “KE-1285” made by Shin-Etsu Chemical Co., Ltd. or the like can be used.

By filling the filling material between adjacent carbon nanotube structures 4 to form the shape retention layer 6, the carbon nanotube structures 4 can be supported so that the carbon nanotube structures 4 do not fall even when used as probes and the adjacent carbon nanotube structures 4 do not come into contact with each other. In addition, the filling material may be filled and cured between the plural carbon nanotubes 41 configuring the carbon nanotube structures 4. In this case, the strength or the durability of the carbon nanotube structures 4 can be improved.

Then, in the cut-off process K6, as shown in FIG. 3E, the top end portions of the carbon nanotube structures 4 and the surface of the shape retention layer 6 are cut off by a means such as laser processing using a laser processing machine or a mechanical processing using a cutter blade. In this way, when the filling material configuring the shape retention layer 6 is attached to the top end portions of the carbon nanotube structures 4, the filling material can be reliably removed. In addition, when the top end portions of each carbon nanotube 41 configuring the carbon nanotube structures 4 are loose or spread, the top end portions can be cut off to align the top end portions of the carbon nanotube structures 4 or to expose the parts with high density on top ends.

Thereafter, in the through hole forming process K7, by a means such as laser processing using a laser processing machine or mechanical processing using a drill or the like, the through holes 24 corresponding to each electrode 3 are formed on the holding plate 2. Thereafter, in the conduction portion forming process K8, the insulation layers 25 of, for example, oxide films are formed on the inner surfaces of the through holes 24, and a material having electrical conductivity is filled into the through holes 24 by a means such as mask patterning or the like to form the conduction portions 5 as shown in FIG. 3F. In this way, the probe structure 1 shown in FIG. 1 is produced.

As shown in FIG. 5, the probe structure 1 having the above configuration can be used as, for example, an inspection jig or the like of a substrate 8 being an inspection target including a glass epoxy substrate, a flexible substrate, a ceramic multilayer wiring substrate, an electrode plate for liquid crystal display or plasma display, a transparent conductive plate for touch panel, a package substrate for semiconductor package, a film carrier and the like.

Specifically, the probe structure 1 is held by a jig holding member not shown in the diagrams, and electrical wires 9 for transmitting signals to an inspection apparatus not shown that includes an ammeter, a voltmeter, a current source or the like are connected to the conduction portions 5 from the second surface 22 side of the holding plate 2. In this way, each carbon nanotube structure 4 is electrically connected to the inspection apparatus, and each carbon nanotube structure 4 can be used as the probe of the inspection apparatus.

Next, the top end portions of the carbon nanotube structures 4 are respectively abutted inspection points 81, 82 of wiring patterns, solder bumps or the like arranged on the substrate 8. Then, a pre-set inspection current flows between the carbon nanotube structure 4 in contact with the inspection point 81 and the carbon nanotube structure 4 in contact with another inspection point 82 to detect a voltage between the inspection points 81, 82, and a value of the voltage is compared with a pre-set reference value, thereby judging the quality of the substrate 8.

As described above, the probe structure 1 includes the holding plate 2 which has the first surface 21 and the second surface 22 in which at least the first surface 21 is insulated, the plurality of electrodes 3 which is formed on the first surface 21 of the holding plate 2 in the state that the electrodes 3 are separated from each other, and the carbon nanotube structures 4 which are erected on the electrodes 3; and the through holes 24 corresponding to the electrodes 3 are formed on the holding plate 2. According to the probe structure 1, contact resistance, which is generated in the conventional technology when base end portions of bulk aggregates of carbon nanotubes are connected to electrode portions and the like for signal transmission after the bulk aggregates are peeled from the substrate, is not generated. As a result, increase in electrical resistance is reduced, the electrical resistance of the probe structure 1 is suppressed to, for example, 150 mΩ or lower and excellent electrical conductivity is obtained. Therefore, there is an advantage that the probe structure 1 can be suitably used as the inspection jig or the like of the substrate inspection apparatus.

In addition, when the conduction portions 5 which extend from the electrodes 3 through the through holes 24 to the second surface 22 side of the holding plate 2 are arranged, electrical connection to the control portion and the like of the substrate inspection apparatus can be easily and appropriately carried out using the conduction portions 5.

In the above first embodiment, because the middle parts of the carbon nanotube structures 4 are converged with a higher density than the rising parts of the carbon nanotube structures 4 rising from the electrodes 3, there is an advantage that the electrical conductivity of the carbon nanotube structures 4 can be further improved and the electrical resistance of the probe structure 1 can be more effectively reduced.

Furthermore, when the carbon nanotube structures 4 are surrounded by the shape retention layer 6 made of the material having insulation property and elasticity and the top end portions of the carbon nanotube structures 4 are set in a state of being exposed from the surface of the shape retention layer 6, the deformation and the damage of the carbon nanotube structures 4 can be effectively prevented while the electrical conductivity of the carbon nanotube structures 4 is maintained.

In addition, as shown in FIG. 2 and FIG. 3A-FIG. 3F, the method for producing the probe structure 1 includes the electrode forming process K1 in which the plurality of electrodes 3 is formed on the first surface 21 of the holding plate 2 in a state that the electrodes 3 are separated from each other, wherein the holding plate 2 has the first surface 21 and the second surface 22, and at least the first surface 21 is insulated; the catalyst arranging process K2 in which the catalysts 31 are respectively arranged on each electrode 3; the carbon nanotube structure generating process K3 in which the plural carbon nanotubes 41 are grown by chemical vapor deposition in the presence of the catalysts 31 to generate the carbon nanotube structures 4 on the electrodes 3; and the through hole forming process K7 in which the through holes 24 corresponding to each electrode 3 are formed on the holding plate 2. According to the producing method of the probe structure 1, there is an advantage that the probe structure 1 which has excellent electrical conductivity and can be suitably used as the inspection jig or the like of the substrate inspection apparatus can be easily and appropriately produced.

When the converging process K4 is included in which the carbon nanotube structures 4 generated in the carbon nanotube structure generating process K3 are soaked in the liquid and then dried, thereby making the middle parts of the carbon nanotube structures 4 be converged with a higher density than the rising parts of the carbon nanotube structures 4 rising from the electrodes 3, the electrical conductivity of the carbon nanotube structures 4 can be more effectively improved. As a result, there is an advantage that the probe structure 1 which can be suitably used as the inspection jig or the like of the substrate inspection apparatus can be easily and appropriately produced.

Furthermore, according to the method for producing the probe structure 1 including the shape retention layer forming process K5 in which the filling material having fluidity is filled to surround the carbon nanotube structures 4, and then the filling material is cured to form the shape retention layer 6 having insulation property and elasticity, there is an advantage that the probe structure 1 having excellent strength and durability while the electrical conductivity of the carbon nanotube structures 4 is maintained can be easily and appropriately produced.

In addition, when the filling material is filled and cured between the plural carbon nanotubes 41 configuring the carbon nanotube structures 4 by using the filling material with extremely high fluidity in the shape retention layer forming process K5, the strength and the durability of the probe structure 1 can be more effectively improved.

According to the method for producing the probe structure 1 further including the cut-off process K6 in which the top end portions of the carbon nanotube structures 4 and the surface of the shape retention layer 6 are cut off, when the filling material configuring the shape retention layer 6 is attached to the top end portions of the carbon nanotube structures 4, the filling material can be reliably removed, and when the top end portions of each carbon nanotube 41 configuring the carbon nanotube structures 4 are loose, the top end portions can be cut off to align the top end portions of the carbon nanotube structures 4. As a result, there is an advantage that the electrical conductivity of the carbon nanotube structures 4 can be effectively improved.

In addition, according to the method for producing the probe structure 1 including the conduction portion forming process in which the material having electrical conductivity is filled into the through holes 24 formed on the holding plate 2 to form the conduction portions 5 which extend form the setting portions of the electrodes 3 to the second surface 22 side of the holding plate 2, there is an advantage that the probe structure 1 in which the electrical connection to the substrate inspection apparatus or the like can be easily and appropriately carried out by using the conduction portions 5 is obtained.

### Second Embodiment

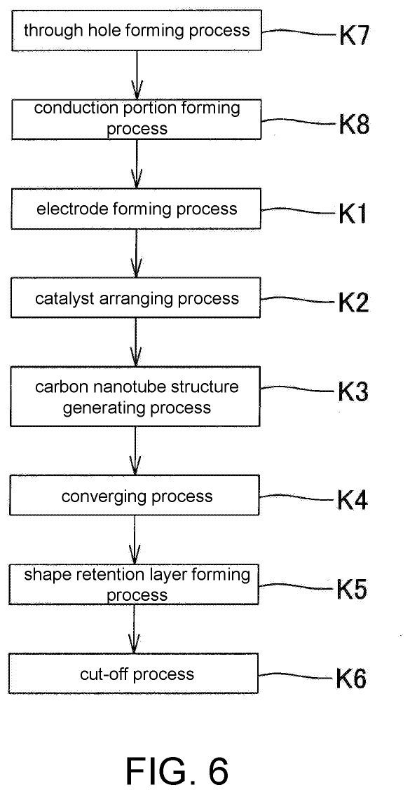

FIG. 6 is a process chart showing a second embodiment of the method for producing the probe structure 1 according to the present invention. The method for producing the probe structure 1 according to the second embodiment is different from the producing method according to the first embodiment shown in FIG. 2 in that after the through holes 24 are formed on the holding plate 2 in the through hole forming process K7, and a material having electrical conductivity is filled into the through holes 24 to form the conduction portions 5 in the conduction portion forming process K8, the electrodes 3 are formed on places corresponding to the through holes 24 on the first surface 21 of the holding plate 2 in the electrode forming process K1, and thereby the electrodes 3 and the conduction portions 5 are connected.

When the the probe structure 1 is configured in this manner, there is also an advantage that the electrical connection to the control portions and the like of the substrate inspection apparatus can be easily and appropriately carried out using the conduction portions 5. Furthermore, the probe structure 1 may not include the conduction portions 5, and the conduction portion forming process K8 may not be performed. Even if the conduction portions 5 are not included, for example, by inserting electrical wires 9 into the through holes 24 and connecting the electrical wires 9 to the electrodes 3, the carbon nanotube structures 4 can also be used as probes.

In addition, between the catalyst arranging process K2 and the carbon nanotube (CNT) structure generating process K3 shown in FIG. 2, the through holes 24 may be formed on the holding plate 2, and the material having electrical conductivity may be filled into the through holes 24 to form the conduction portions 5.

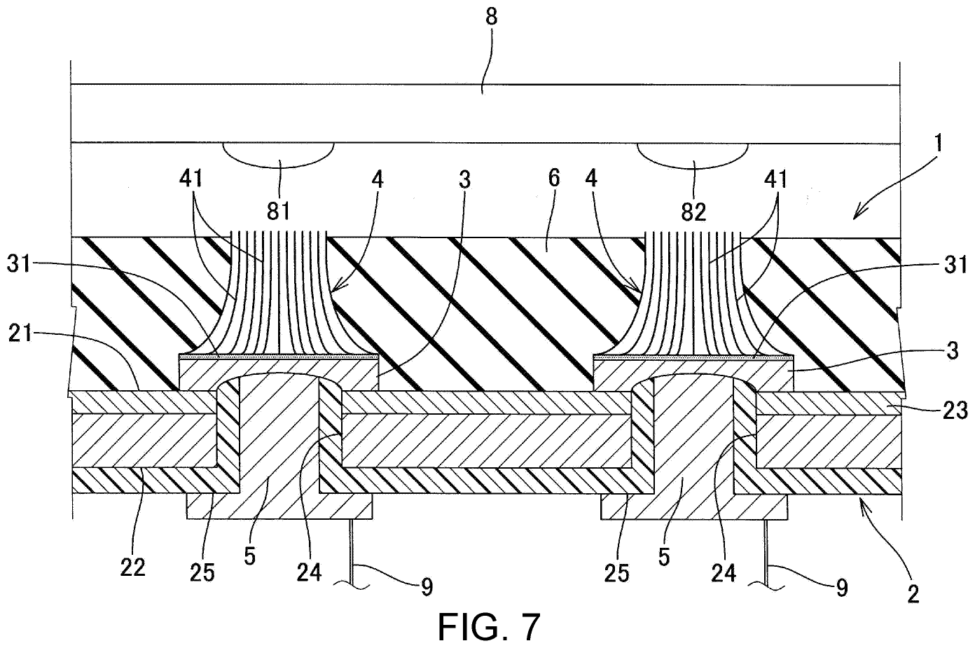

In addition, as shown in FIG. 7, the conduction portions 5 may be formed to be electrically continuous from the through holes 24 of the holding plate 2 to positions covering the second surface 22 side of the holding plate 2, and the positions covering the second surface 22 may be used as connection portions of the conduction portions 5 and the electrical wires 9. In this case, when the electrical wires 9 are connected to the conduction portions 5, even if the parts of the conduction portions 5 positioned inside the through holes 24 are plastically deformed easily even under a comparatively weak force, or adhesive strength between inner walls of the through holes 24 and the conduction portions 5 are not sufficiently strong, the electrical wires 9 can be firmly connected to the conduction portions 5 without forces applied from the electrical wires 9 to the conduction portions 5 inside the through holes 24 being transmitted to the electrodes 3 and the electrodes 3 being peeled from the holding plate 2 or from the insulation film 23 on the first surface 21 of the holding plate 2 or the electrodes 3 being broken and deformed. In a view from the second surface side, the connection portions may be a shape concentric with the through holes 24, or a shape such as an ellipse eccentric from centers of the through holes 24. The connection portions and the conduction portions 5 inside the through holes 24 can use the same material or use different materials. The connection portions and the conduction portions 5 inside the through holes 24 may be formed by the same process, or a process for forming the conduction portions 5 inside the through holes 24 and a process for forming the connection portions on the second surface 22 side may be different processes.

That is, the probe structure according to one aspect of the present invention includes a holding plate which has a first surface and a second surface in which at least the first surface is insulated, a plurality of electrodes which is formed on the first surface of the holding plate in a state that the plurality of electrodes is separated from each other, and carbon nanotube structures which are erected on the electrodes respectively; and through holes which correspond to the electrodes are formed on the holding plate.

According to this configuration, unlike the conventional technology in which after bulk aggregates of carbon nanotubes are peeled from the substrate, electrical resistance increases due to contact resistance as in the case when base end portions of the bulk aggregates are connected to electrode portions or the like, the electrical resistance of the probe structure is suppressed to, for example, below 150 mΩ and excellent conductivity is obtained, and thus the probe structure can be suitably used as a probe for detecting electrical signals.

In addition, the probe structure further includes conduction portions which extend from each of the electrodes through the through holes to the second surface side of the holding plate.

According to this configuration, the electrodes formed on the first surface of the holding plate and an external apparatus for which the electrical signals are to be detected can be easily and appropriately connected by using the conduction portions.

In addition, the middle part of each carbon nanotube structure is converged further than the rising part rising from each electrode of each of the carbon nanotube structures.

According to this configuration, there is an advantage that the conductivity of the carbon nanotube structures can be further improved to more effectively reduce the electrical resistance of the probe structure.

In addition, each carbon nanotube structure may be surrounded by a shape retention layer made of a material having insulation property and elasticity, and top end portions of each of the carbon nanotube structures may be exposed from a surface of the shape retention layer.

According to this configuration, deformation and damage of the carbon nanotube structures can be effectively prevented while the electrical conductivity of the carbon nanotube structures is maintained.

The method for producing probe structure according to one aspect of the present invention includes an electrode forming process in which a plurality of electrodes is formed on a first surface of a holding plate in the state that the plurality of electrodes is separated from each other, wherein the holding plate has the first surface and a second surface, and at least the first surface is insulated; a catalyst arranging process in which catalysts are arranged on the plurality of electrodes; a carbon nanotube structure generating process in which plural carbon nanotubes are grown by chemical vapour deposition in the presence of the catalysts to generate a carbon nanotube structure on each of the electrodes; and a through hole forming process in which through holes corresponding to the electrodes respectively are formed in the holding plate.

According to this configuration, there is an advantage that the probe structure which has excellent electrical conductivity and can be suitably used as an inspection jig or the like of a substrate inspection apparatus can be easily and appropriately produced.

In addition, the producing method of probe structure further includes a converging process in which each of the carbon nanotube structures generated in the carbon nanotube structure generating process is soaked in a liquid and then dried, and thereby a middle part of each of the carbon nanotube structures is converged further than a rising part rising from each electrode of each of the carbon nanotube structures.

According to this configuration, there is an advantage that because the electrical conductivity of the carbon nanotube structures can be further improved, the probe structure which can be more suitably used as a probe for detecting the electrical signals can be easily and appropriately produced.

In addition, the producing method of probe structure further includes a shape retention layer forming process in which a filling material having fluidity is filled to surround each of the carbon nanotube structures, and then the filling material is cured to form a shape retention layer having insulation property and elasticity.

According to this configuration, there is an advantage that the probe structure which has excellent strength and durability while the electrical conductivity of the carbon nanotube structures is maintained can be easily and appropriately produced.

In addition, in the shape retention layer forming process, the filling material having fluidity may be filled and cured between the plural carbon nanotubes configuring the carbon nanotube structures.

According to this configuration, the strength and durability of the probe structure can be more effectively improved.

In addition, the producing method of probe structure further includes a cut-off process in which top end portions of each of the carbon nanotube structures and the surface of the shape retention layer are cut off.

According to this configuration, when the filling material configuring the shape retention layer is attached to the top end portions of the carbon nanotube structures, the filling material can be reliably removed. Furthermore, when the top end portions of each carbon nanotube configuring the carbon nanotube structure are loose, the top end portions can be cut off to align the top end portions of the carbon nanotube structures. As a result, the electrical conductivity of the carbon nanotube structures can be effectively improved.

In addition, the producing method of probe structure further includes a conduction portion forming process in which a material having electrical conductivity is filled into the through holes formed on the holding plate, and conduction portions which extend from the first surface of the holding plate to the second surface side of the holding plate are formed.

According to this configuration, there is an advantage that the probe structure in which the electrodes formed on the first surface of the holding plate and the control portion and the like of the substrate inspection apparatus can be easily and appropriately connected by using the conduction portions can be obtained.

Furthermore, after the through holes are formed on the holding plate in the through hole forming process, and the material having electrical conductivity is filled into the through holes to form the conduction portions in the conduction portion forming process, the electrodes may be formed on the first surface of the holding plate in the electrode forming process.

In this configuration, the probe structure in which the electrodes formed on the first surface of the holding plate and the control portion and the like of the substrate inspection apparatus can be easily and appropriately connected by using the conduction portions can be obtained.

According to the aforementioned probe structure and the producing method therefore, the electrical resistance of the probe structure can be prevented from increasing to obtain excellent electrical conductivity. In addition, according to the aforementioned producing method, the probe structure having excellent electrical conductivity can be easily and appropriately produced.

This application is based on Japanese patent application 2017-054640 applied on Mar. 21, 2017, and contents of Japanese patent application 2017-054640 are included in this application. Furthermore, specific embodiments or examples made in items of modes for carrying out the invention are merely used to clarify technical contents of the present invention, and the present invention should not be limited only to such specification examples and construed narrowly.

### DESCRIPTION OF THE SYMBOLS

1 probe structure

2 holding plate

3 electrode

4 carbon nanotube structure

5 conduction portion

6 shape retention layer

21 first surface

22 second surface

24 through hole

25 insulation layer

31 catalyst

41 carbon nanotube

1. A probe structure, comprising:
a holding plate which has a first surface and a second surface, at least the first surface being insulated;
a plurality of electrodes which is formed on the first surface of the holding plate in a state that the plurality of electrodes is separated from each other; and
carbon nanotube structures which are erected respectively on the electrodes;
wherein through holes which correspond to the electrodes respectively are formed on the holding plate.

2. The probe structure according to claim 1, further comprising conduction portions which extend respectively from the electrodes through the through holes to the second surface side of the holding plate.

3. The probe structure according to claim 1, wherein a middle part of each of the carbon nanotube structures is converged further than a rising part rising from each electrode of each of the carbon nanotube structures.

4. The probe structure according to claim 1, wherein each of the carbon nanotube structures is surrounded by a shape retention layer including a material having insulation property and elasticity, and top end portions of each of the carbon nanotube structure are exposed from a surface of the shape retention layer.

5. A method for producing probe structure, comprising:
an electrode forming process in which a plurality of electrodes is formed on a first surface of a holding plate in a state that the plurality of electrodes is separated from each other, wherein the holding plate has the first surface and a second surface, and at least the first surface is insulated;
a catalyst arranging process in which catalysts are arranged on the plurality of electrodes;
a carbon nanotube structure generating process in which a plurality of carbon nanotubes is grown by chemical vapor deposition in the presence of the catalysts to generate carbon nanotube structures on the electrodes respectively; and
a through hole forming process in which through holes corresponding to the electrodes respectively are formed in the holding plate.

6. The method for producing probe structure according to claim 5, further comprising a converging process in which each of the carbon nanotube structures generated in the carbon nanotube structure generating process is soaked in a liquid and then dried, and thereby a middle part of each of the carbon nanotube structures is converged further than a rising part rising from each electrode of each of the carbon nanotube structures.

7. The method for producing probe structure according to claim 5, further comprising a shape retention layer forming process in which a filling material having fluidity is filled to surround each of the carbon nanotube structures, and then the filling material is cured to form a shape retention layer having insulation property and elasticity.

8. The method for producing probe structure according to claim 7, wherein in the shape retention layer forming process, the filling material having fluidity is filled and cured between the plurality of carbon nanotubes configuring the carbon nanotube structures.

9. The method for producing probe structure according to claim 7, further comprising a cut-off process in which top end portions of each of the carbon nanotube structures and a surface of the shape retention layer are cut off.

10. The method for producing probe structure according to claim 5, further comprising a conduction portion forming process in which a material having electrical conductivity is filled into the through holes formed on the holding plate, and conduction portions which extend from setting portions of the electrodes to the second surface side of the holding plate are formed.

11. The method for producing probe structure according to claim 10, wherein after the through holes are formed in the holding plate in the through hole forming process, and the material having electrical conductivity is filled into the through holes to form the conduction portions in the conduction portion forming process, the electrodes are formed on the first surface of the holding plate in the electrode forming process.

12. The probe structure according to claim 2, wherein a middle part of each of the carbon nanotube structures is converged further than a rising part rising from each electrode of each of the carbon nanotube structures.

13. The probe structure according to claim 2, wherein each of the carbon nanotube structures is surrounded by a shape retention layer including a material having insulation property and elasticity, and top end portions of each of the carbon nanotube structure are exposed from a surface of the shape retention layer.

14. The probe structure according to claim 3, wherein each of the carbon nanotube structures is surrounded by a shape retention layer including a material having insulation property and elasticity, and top end portions of each of the carbon nanotube structure are exposed from a surface of the shape retention layer.

15. The probe structure according to claim 12, wherein each of the carbon nanotube structures is surrounded by a shape retention layer including a material having insulation property and elasticity, and top end portions of each of the carbon nanotube structure are exposed from a surface of the shape retention layer.

16. The method for producing probe structure according to claim 6, further comprising a shape retention layer forming process in which a filling material having fluidity is filled to surround each of the carbon nanotube structures, and then the filling material is cured to form a shape retention layer having insulation property and elasticity.

17. The method for producing probe structure according to claim 16, wherein in the shape retention layer forming process, the filling material having fluidity is filled and cured between the plurality of carbon nanotubes configuring the carbon nanotube structures.

18. The method for producing probe structure according to claim 8, further comprising a cut-off process in which top end portions of each of the carbon nanotube structures and a surface of the shape retention layer are cut off.

19. The method for producing probe structure according to claim 6, further comprising a conduction portion forming process in which a material having electrical conductivity is filled into the through holes formed on the holding plate, and conduction portions which extend from setting portions of the electrodes to the second surface side of the holding plate are formed.

20. The method for producing probe structure according to claim 19, wherein after the through holes are formed in the holding plate in the through hole forming process, and the material having electrical conductivity is filled into the through holes to form the conduction portions in the conduction portion forming process, the electrodes are formed on the first surface of the holding plate in the electrode forming process.
